(19) United States
(12) Patent Application Publication
(10) Pub. No.: US 2016/0293636 A1
(43) Pub. Date: Oct. 6, 2016

(54) THIN FILM TRANSISTOR AND FABRICATION METHOD THEREOF, ARRAY SUBSTRATE, AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei City (CN)

(72) Inventors: Zhixiang ZOU, Beijing (CN); Binbin CAO, Beijing (CN); Yinhu HUANG, Beijing (CN)

(21) Appl. No.: 15/072,940

(22) Filed: Mar. 17, 2016

(30) Foreign Application Priority Data
Apr. 3, 2015 (CN) 201510159095.6

(51) Int. Cl. H01L 27/12; H01L 29/49; H01L 21/3213; H01L 29/66

(52) U.S. Cl. CPC H01L 27/124; H01L 29/66742; H01L 27/1222; H01L 29/4908; H01L 21/32136

(57) ABSTRACT

A thin film transistor and a fabrication method thereof, an array substrate, and a display device are provided. The fabrication method comprises: forming a gate line on a base substrate; performing a treatment for alleviating a bulge of the gate line on the base substrate with the gate line formed thereon, and forming a gate insulating layer on the base substrate after the treatment. Thereby, a problem of bulge of the gate line occurring in a fabrication process of the thin film transistor can be alleviated or even avoided, so that resistance of the gate line is uniform, which further renders uniform display of the display device, and improves display quality of the display device.

### TECHNICAL FIELD

Embodiments of the present disclosure relate to a thin film transistor and a fabrication method thereof, an array substrate, and a display device.

### BACKGROUND

In production of a display device, a thin-film transistor (TFT) plays a very important role, an ON state of the thin film transistor is mainly used for fast charging a pixel capacitor of the display device, and an OFF state of the thin film transistor is used for maintaining a voltage of the pixel capacitor, so as to achieve fast response and good storage. Due to a very high ratio of on-state current (Ion) and an off-state current (Ioff) and a steep transfer characteristic, the thin film transistor, as a non-linear switching element, is widely used in fields such as a large-area liquid crystal display and an image sensor of a contact type.

However, in a production process of the thin film transistor, a problem of bulge is apt to occur to a gate line, so that resistance of the gate line is nonuniform, which further renders nonuniform display of the display device, and poor display quality of the display device.

### SUMMARY

Embodiments of the present invention provides a thin film transistor and a fabrication method thereof, an array substrate, and a display device, which can alleviate or even avoid a problem of bulge of the gate line occurring in a fabrication process of the thin film transistor, so that resistance of the gate line is uniform, which further renders uniform display of the display device, and improves display quality of the display device

An embodiment of the present invention provides a fabrication method, and the fabrication method comprises: forming a gate line on a base substrate; performing a treatment for alleviating a bulge of the gate line on the base substrate with the gate line formed thereon, and forming a gate insulating layer on the base substrate after the treatment.

An embodiment of the present invention provides a thin film transistor, and the thin film transistor is a thin film transistor fabricated by using the method according to an embodiment of the present invention.

An embodiment of the present invention provides an array substrate, comprising the thin film transistor according to an embodiment of the present invention.

An embodiment of the present invention provides a display device, comprising the array substrate according to an embodiment of the present invention.

### BRIEF DESCRIPTION OF THE DRAWINGS

In order to clearly illustrate the technical solution of the embodiments of the invention, the drawings of the embodiments will be briefly described in the following; it is obvious that the described drawings are only related to some embodiments of the invention and thus are not limitative of the invention.

FIG. 1 is a structural schematic diagram of an existing amorphous silicon thin film transistor of a bottom-gate anti-stack type;

FIG. 2 is an overall flow schematic diagram of a fabrication method of a thin film transistor provided by an embodiment of the present disclosure;

FIG. 3 is a specific flow schematic diagram of a first type of fabrication method of a thin film transistor provided by an embodiment of the present disclosure;

FIG. 4 is a specific flow schematic diagram of a second type of fabrication method of a thin film transistor provided by an embodiment of the present disclosure;

FIG. 5 is a specific flow schematic diagram of a third type of fabrication method of a thin film transistor provided by an embodiment of the present disclosure;

FIG. 6 is a specific flow schematic diagram of a fourth type of fabrication method of a thin film transistor provided by an embodiment of the present disclosure.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Embodiments of the present disclosure provide a thin film transistor and a fabrication method thereof, an array substrate and a display device, for alleviating or even avoiding the bulge problem of a gate line occurring in a fabrication process of the thin film transistor, so that resistance of the gate line is uniform, which further renders uniform display of the display device, and improves display quality of the display device.

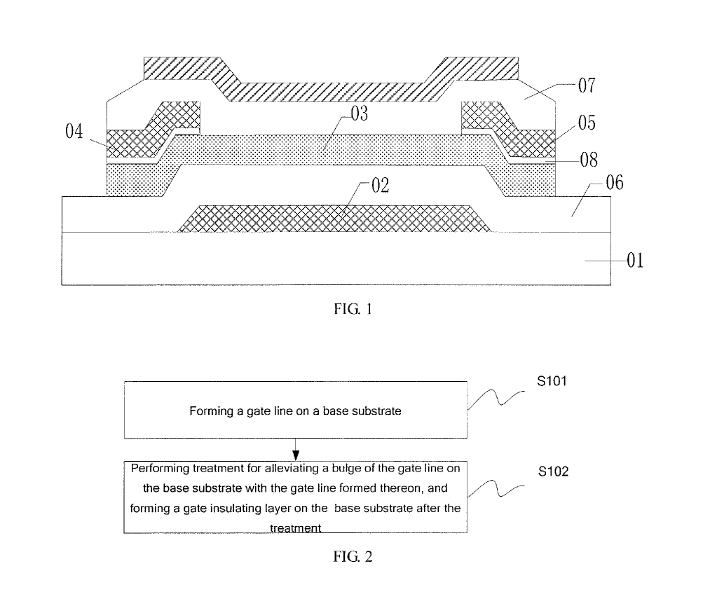

A structure of an amorphous silicon thin film transistor of a bottom-gate anti-stack type as shown in FIG. 1, comprises: a base substrate 01; a gate electrode 02, disposed on the base substrate 01; an active layer 03, disposed on the gate electrode 02 and insulated from the gate electrode 02; a source electrode 04 and a drain electrode 05, disposed opposite to each other and respectively electrically connected with the active layer 03, when a current is applied to the gate electrode 02 through a circuit installed on the base substrate 01, a current applied to the source electrode 04 is transmitted to the drain electrode 05 through the active layer 03, to drive a pixel unit of a display device, so as to display an image. A gate insulating layer 06 is disposed between the gate electrode 02 and the active layer 03, a passivation layer 07 is disposed above the source electrode 04 and the drain electrode 05, wherein, the gate insulating layer 06 is typically made of an a-SiNx thin film, the active layer 03 is typically made of an a-Si:H thin film, the passivation layer 07 is typically made of an a-SiNx thin film, and the gate electrode 02, the source electrode 04 and the drain electrode 05 are typically made of metal, for example, copper (Cu). To improve a contact characteristic of the source electrode 04, the drain electrode 05 and the a-Si:H thin film, a thin a-Si:H thin film of an n+ type is inserted therebetween as an ohmic contact layer 08.

Nowadays, a high-resolution and high-definition flat panel display device is generally favored by people. Delay of an image signal becomes one of key factors which restrict the high-resolution and high-definition flat panel display device. However, the delay of the image signal is mainly determined by signal resistance and related capacitance which are determined by the gate electrode and the gate line on the array substrate. Currently, the gate electrode and the gate line are made of metal Cu which has a lower resistance, so as to reduce the resistance of the gate electrode and the gate line. However, in a fabrication environment of high temperature deposition for the gate insulating layer, a copper conducting wire is easy to form a bulge, resulting in difference in resistance of the copper conducting wire. Thereby, when a gate electrode scanning line is turned on, a pixel is charged, and due to different in resistance of the gate electrode scanning line, some pixels are not charged sufficiently, which renders uneven brightness of an image display picture, and seriously affects display quality of the image. In addition, as the gate insulating layer has a characteristic that a film layer falls off, this characteristic of the gate insulating layer is generally alleviated by preheat of longer time and by N₂ plasma treatment. However, both the preheat of longer time and the N₂ plasma treatment will aggravate the problem of bulge of the copper conducting wire.

Therein, the N₂ plasma treatment specifically refers to that before the gate insulating layer (GI) is deposited, nitrogen (N₂) is excited by a preset power to form a plasma and then Cu and a surface of the substrate is bombarded, which improves the characteristic of a deposition surface of the GI; the N₂ plasma treatment is a technological means of treating a film surface by plasma.

With reference to FIG. 2, a fabrication method of a thin film transistor provided by an embodiment of the present disclosure comprises steps of:

S101: forming a gate line on a base substrate;

S102: performing treatment for alleviating a bulge of the gate line on the base substrate with the gate line formed thereon, and forming a gate insulating layer on the treated base substrate.

By using this method: performing treatment for alleviating a bulge of the gate line on the base substrate having the gate line formed thereon, and forming a gate insulating layer on the treated base substrate, the problem of bulge of the gate line occurring in a fabrication process of the thin film transistor is alleviated or even avoided, so that resistance of the gate line is uniform, which further renders uniform display of the display device, and improves display quality of the display device.

Exemplarily, the method further comprises:

Forming an active layer, a source electrode, a drain electrode, a passivation layer, a common electrode and a pixel electrode on the base substrate with the gate insulating layer formed thereon, respectively.

Exemplarily, the performing treatment for alleviating a bulge of the gate line on the base substrate with the gate line formed thereon, and forming a gate insulating layer on the treated base substrate, includes:

Directly forming the gate insulating layer on the base substrate with the gate line formed thereon; or

Performing plasma treatment on the gate line with a preset plasma treatment power, and forming the gate insulating layer on the base substrate with the gate line formed thereon after the plasma treatment, wherein, the preset plasma treatment power is less than 8 kilowatts; or,

Performing preheat treatment on the base substrate with the gate line formed thereon according to preset preheat time, and forming the gate insulating layer on the base substrate with the gate line formed thereon after the preheat treatment, wherein, the preset preheat time is less than 60 seconds; or,

Performing the preheat treatment on the base substrate with the gate line formed thereon according to preset preheat time, performing the plasma treatment on the gate line with preset plasma treatment power, and forming the gate insulating layer on the base substrate with the gate line formed thereon after the preheat treatment and the plasma treatment, wherein, the preset plasma treatment power is less than 8 kilowatts, and/or, the preset preheat time is less than 60 seconds.

Exemplarily, the preheat time is greater than or equal to 10 seconds, and less than or equal to 20 seconds.

Exemplarily, the preset plasma treatment power is greater than or equal to 5 kilowatts, and less than or equal to 7 kilowatts.

Exemplarily, the performing plasma treatment on the gate line, may be performing plasma treatment on the gate line by using nitrogen.

Exemplarily, a material of the gate line includes copper. For example, the gate line according to the embodiment of the present disclosure may be a gate line entirely made of copper, and may also be a gate line made of an alloy comprising copper and other metals, or may be a gate line made of other metals, for example, may be a gate line made of chromium. In short, for all the metal wires to which the bulge is apt to occur, the problem can be alleviated by the technical solution provided by the embodiment of the present disclosure.

### A First Embodiment

With reference to FIG. 3, a fabrication method of a thin film transistor provided by the embodiment of the present disclosure comprises:

S201: forming a gate line on a base substrate;

S202: directly forming a gate insulating layer on the base substrate with the gate line formed thereon;

In this embodiment, the gate insulating layer is directly formed on the base substrate with the gate line formed thereon, that is, a step of N₂ plasma treatment is omitted; since the plasma treatment is to perform a bombarding treatment by plasma obtained by heating, omission of this step will reduce a heating temperature of the gate line to a large extent, so as to lower a temperature for heating the gate line, and avoid a bulge of the gate line.

S203: Forming an active layer, a source electrode, a drain electrode, a passivation layer, a common electrode and a pixel electrode on the base substrate with the gate insulating layer formed thereon, respectively.

### A Second Embodiment

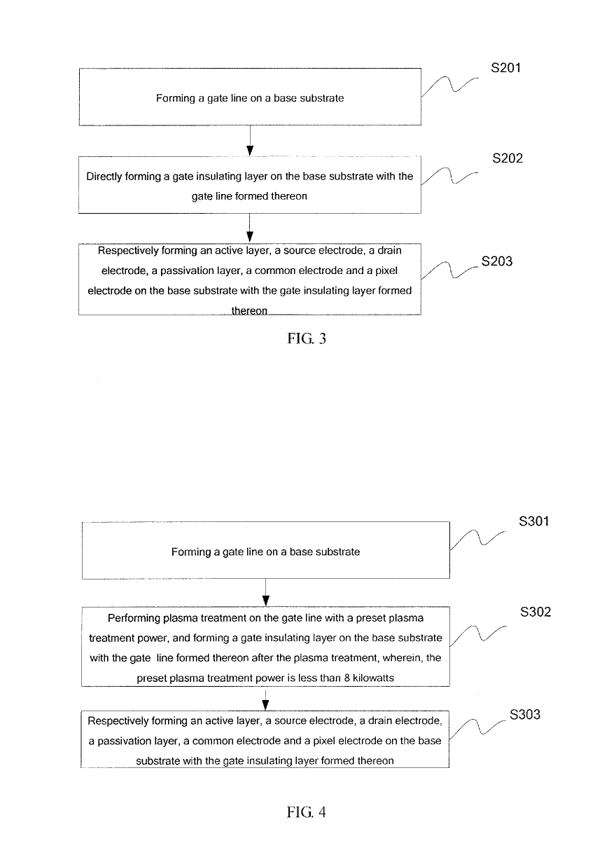

With reference to FIG. 4, a fabrication method of a thin film transistor provided by the embodiment of the present disclosure comprises:

S301: forming a gate line on a base substrate;

S302: performing plasma treatment on the gate line with a preset plasma treatment power, and forming a gate insulating layer on the base substrate with the gate line formed thereon after the plasma treatment, wherein, the preset plasma treatment power is less than 8 kilowatts.

This embodiment reduces the power of the plasma treatment; since the plasma treatment is to perform a bombarding treatment by plasma obtained by heating, reduction of the power of the plasma treatment will just reduce a temperature of the plasma treatment, so as to lower a temperature for heating the gate line, and avoid a bulge of the gate line.

S303: forming an active layer, a source electrode, a drain electrode, a passivation layer, a common electrode and a pixel electrode on the base substrate with the gate insulating layer formed thereon, respectively.

### A Third Embodiment

With reference to FIG. 5, a fabrication method of a thin film transistor provided by the embodiment of the present disclosure comprises:

S401: forming a gate line on a base substrate;

S402: performing preheat treatment on the base substrate with the gate line formed thereon according to preset preheat time, and forming a gate insulating layer on the base substrate with the gate line formed thereon after the preheat treatment, wherein, the preset preheat time is less than 60 seconds;

This embodiment, by reducing the preheat time, shortens time for heating the gate line, so as to lower a temperature for heating the gate line, and avoid a bulge of the gate line.

Through specific experiments, it can be known that when the preheat time is within a range of 10 seconds and 20 seconds, the problem of bulge of the gate line will be alleviated to a maximum degree, and oxidation of the gate line is slowed down.

S403: Forming an active layer, a source electrode, a drain electrode, a passivation layer, a common electrode and a pixel electrode on the base substrate with the gate insulating layer formed thereon, respectively.

### A Fourth Embodiment

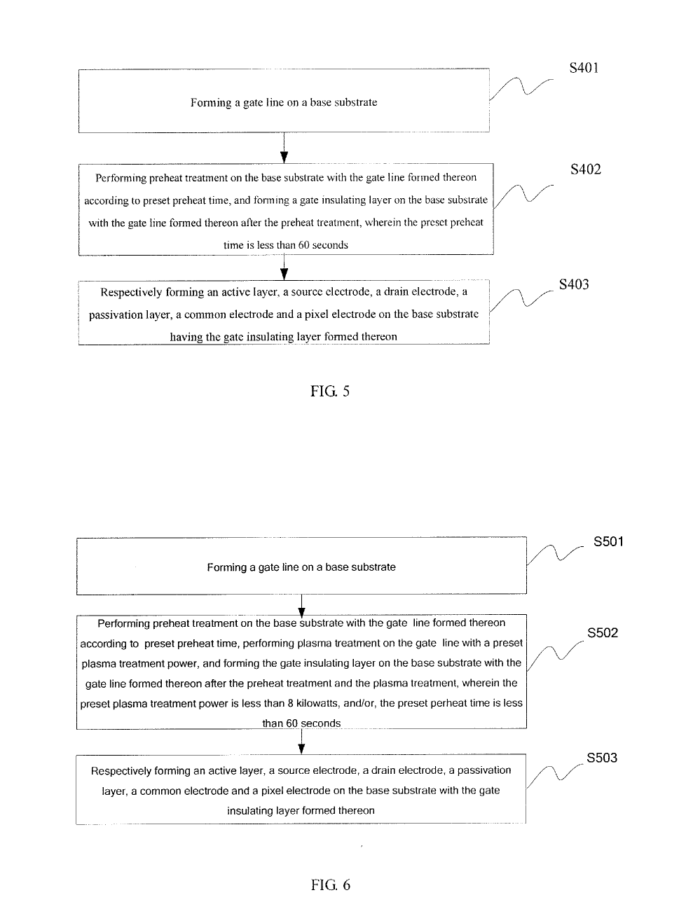

With reference to FIG. 6, a fabrication method of a thin film transistor provided by the embodiment of the present disclosure comprises:

S501: forming a gate line on a base substrate;

S502: performing preheat treatment on the base substrate with the gate line formed thereon according to preset preheat time, performing plasma treatment on the gate line with a preset plasma treatment power, and forming the gate insulating layer on the base substrate with the gate line formed thereon after the preheat treatment and the plasma treatment, wherein, the preset plasma treatment power is less than 8 kilowatts, and/or, the preset preheat time is less than 60 seconds.

In this step, the preheat treatment may be firstly performed and then the plasma treatment is performed; or, the plasma treatment may be firstly performed and then the preheat treatment is performed.

In this embodiment, the preheat treatment and the plasma treatment are combined; and as long as either treatment, as compared with the prior art, lowers the heating temperature of the gate line, the bulge of the gate line can be alleviated or avoided.

S503: Forming an active layer, a source electrode, a drain electrode, a passivation layer, a common electrode and a pixel electrode on the base substrate with the gate insulating layer formed thereon, respectively.

An embodiment of the present disclosure provides a thin film transistor, and the thin film transistor is a thin film transistor fabricated by using the method provided by the embodiment of the present disclosure.

An embodiment of the present disclosure provides an array substrate, comprising the thin film transistor provided by the embodiment of the present disclosure.

An embodiment of the present disclosure provides a display device, comprising the array substrate provided by the embodiment of the present disclosure.

In summary, in an embodiment of the present disclosure, the treatment for alleviating the bulge of the gate line on the base substrate with the gate line formed thereon is performed, and then, the gate insulating layer is formed on the treated base substrate, which alleviates or even avoids the problem of bulge of the gate line occurring in the fabrication process of the thin film transistor, so that the resistance of the gate line is uniform, which further renders uniform display of the display device, and improves the display quality of the display device.

It is obvious that those skilled in the art can carry out various changes and improvements to the disclosure without departing from the spirit and scope of the present disclosure. In this case, if such changes and improvements fall into the scope of the claims of the present disclosure and equivalents thereof, the present disclosure intends to contain these changes and improvements therein.

The present application claims priority of Chinese Patent Application No. 201510159095.6 filed on Apr. 3, 2015, the disclosure of which is incorporated herein by reference in its entirety as part of the present application.

1. A fabrication method of a thin film transistor, comprising:
forming a gate line on a base substrate;
performing a treatment for alleviating a bulge of the gate line on the base substrate with the gate line formed thereon, and forming a gate insulating layer on the base substrate after the treatment.

2. The method according to claim 1, further comprising:
forming an active layer, a source electrode, a drain electrode, a passivation layer, a common electrode and a pixel electrode on the base substrate with the gate insulating layer formed thereon.

3. The method according to claim 1, wherein the performing the treatment for alleviating a bulge of the gate line on the base substrate with the gate line formed thereon, and forming a gate insulating layer on the base substrate after the treatment, comprises:
directly forming the gate insulating layer on the base substrate with the gate line formed thereon; or
performing a plasma treatment on the gate line with a preset plasma treatment power, and forming the gate insulating layer on the base substrate with the gate line formed thereon after the plasma treatment; or
performing a preheat treatment on the base substrate with the gate line formed thereon according to preset preheat time, and forming the gate insulating layer on the base substrate with the gate line formed thereon after the preheat treatment; or
performing a preheat treatment on the base substrate with the gate line formed thereon according to preset preheat time, performing a plasma treatment on the gate line with preset plasma treatment power, and forming the gate insulating layer on the base substrate with the gate line formed thereon after the preheat treatment and the plasma treatment.

4. The method according to claim 3, wherein the preset plasma treatment power is less than 8 kilowatts, and the preheat time is less than 60 seconds.

5. The method according to claim 4, wherein the preheat time is greater than or equal to 10 seconds, and less than or equal to 20 seconds.

6. The method according to claim 4, wherein the preset plasma treatment power is greater than or equal to 5 kilowatts, and less than or equal to 7 kilowatts.

7. The method according to claim 3, wherein the performing plasma treatment on the gate line comprises: performing plasma treatment on the gate line by using nitrogen.

8. The method according to claim 1, wherein a material of the gate line includes copper.

9. A thin film transistor, wherein the thin film transistor is a thin film transistor fabricated by using the method according to claim 1.

10. An array substrate, comprising the thin film transistor according to claim 9.

11. A display device, comprising the array substrate according to claim 10.
